(19) United States
(12) Patent Application Publication
(10) Pub. No.: US 2022/0050201 A1
(43) Pub. Date: Feb. 17, 2022

(54) FMCW IMAGING LIDAR BASED ON COHERENT PIXEL ARRAY

(71) Applicant: Litexel Inc., West Covina, CA (US)

(72) Inventors: Xiaochen Sun, Chino Hills, CA (US); Lingxuan Zhang, West Covina, CA (US); Ningning Feng, Acadia, CA (US)

(73) Assignee: Litexel Inc., West Covina, CA (US)

(21) Appl. No.: 16/995,479

(22) Filed: Aug. 17, 2020

(51) Int. Cl. G01S 17/34; G01S 17/89; G01S 7/481; G02B 27/28; G02B 6/12; H01L 27/146

(52) U.S. Cl. CPC G01S 17/34; G01S 17/89; G01S 7/4817; G02B 2006/1215; G02B 6/12; H01L 27/14609; G02B 27/283

(57) ABSTRACT

A frequency-modulated continuous wave (FMCW) imaging light detection and ranging (LiDAR) system includes an integrated photonic circuit based coherent pixel array sensor having a large number of coherent pixels. Each pixel receives both the frequency-modulated signal light from a local light source (LO) and the returned signal light reflected from a section of the target scene through an imaging optical system. At each pixel, the LO light and the returned light are mixed locally by an optical mixer and then detected locally by an integrated photodetector. The electrical signal from each pixel is used to calculate scene distance using FMCW LiDAR principles. The LO signal is distributed into each pixel by an on-chip optical switch and routing circuit. An optical phased array may be used to split the source beam into the LO light and the target illumination light and to steer the illumination light.

### BACKGROUND OF THE INVENTION

### Field of The Invention

The invention relates to a light detection and ranging (LiDAR) system that images a target scene with an array of optically coherent pixels, each of which performing frequency-modulated continuous wave (FMCW) depth and velocity calculation.

### Description of Related Art

Light detection and ranging (LiDAR) technology has been widely used for terrestrial and aerial mapping and in recent year its adoption gained great popularity and momentum for autonomous driving and a variety of smart robotic machines. A LiDAR system generally emits pulsed or modulated laser light, calculates the depth, i.e. the distance, of one or many spots of a 2-dimensional (2D) scene from the reflected light and generates a point cloud which describes the depth information of the scene.

A 2D scene can be mapped by either steering or scanning a well-collimated optical beam to shine on each spot at a time or by using a camera lens system to image the scene onto a sensor with an array of pixels, each of which corresponds to a spot of the scene. The scanning approach has been widely used for relatively long range, e.g. tens or hundreds of meters, that is required by many autonomous driving applications. It only shines signal light on a small spot at a time instead of illuminating the whole scene therefore, less emitted light power is needed at a given minimally required returned signal light power for accurate distance calculation. This lower light power requirement is essential in practice for laser availability and the compliance with eye safety. On the other hand, the imaging approach has mostly been used for short range, e.g. less than ten meters, that often finds applications in smartphones and other consumer electronics. The imaging approach is generally not able to be used for more than ten meters because in compliance with eye safety the returned light power split by each pixel at a longer distance may be below detectable levels.

In the imaging approach, the sensitivity of a sensor pixel is the key to increase the maximally detectable range at limited light emission power constrained by the required eye-safety standards. However, in traditional photo sensors incoming photons are directly detected by a photodiode or a photogate in voltage mode or charge mode which poses theoretical sensitivity limits due to photocurrent shot noise and circuit noise. Compared with color or IR camera imaging, using such approach for distance measurement suffers more from such noises because it relies on the calculation of multiple modulated signals with different phase delays. Recently an avalanche photodiode operating at Geiger mode is used to form so called single-photon avalanche detector (SPAD) which may detect a single photon and achieves high sensitivity. However, the SPAD suffers from highly probabilistic photon detection and is susceptible to many noise sources from dark electrons and ambient photons which must be suppressed by large number of spatially correlated and temporarily repeated measurement. The requirement of obtaining spatial correlation with multiple nearby pixels and the complexity in read-out circuits limit the effective number of pixels that may fit in a sensor chip with practical sizes.

In wireless and optical communication applications, coherent technology has been often used for significantly enhancing the signal-to-noise ratio (SNR) by mixing the small amount of a source signal with a weak incoming signal. Based on a similar principle, a frequency-modulated continuous wave (FMCW) approach was adopted in both radio frequency and optical frequency to calculate the distance to a target by the beating frequency from the mixing of a frequency-modulating source signal (local oscillator or LO) and the returned signal (R) reflected from the target. In optical frequency that a LiDAR module operates, such optical mixing is usually achieved by discrete components such as a prism beam combiner or by a photonic component such as a waveguide beam combiner on a photonic integrated circuit (PIC). The optical mixing requires both temporal and spatial coherence of the local oscillator and the received signal so that a co-axial configuration is mostly adopted for either case. A typical conceptual design is shown in FIG. 1 where a FMCW device includes at least a laser source, a collimating lens, a beam splitter BS (doubled as an optical mixer) with a 45°-arranged semi-reflective semi-transmissive interface inside the beam splitter, a photodetector and is configured in such a way that the laser and the photodetector is effectively co-axial through the help of the beam splitter. Such co-axial configuration generally prevents making the design of a photodetector array for the imaging approach therefore an external scanning approach must be adopted to scan the output beam in order to obtain the depth mapping of the target scene.

### SUMMARY

Combining multiple copies of the discrete optical components to make a large scale FMCW array sensor is believed to be practically difficult and cost prohibitive which is responsible for the lack of FMCW pixel array sensor products in the market today. Thanks to the emergence of Si based photonic integrated circuits (PIC) technology, it is now feasible to make a larger number of FMCW array on a single chip that may achieve much better distance detection sensitivity than current technology and enables a new FMCW imaging scheme for LiDAR and 3D sensing. The FMCW imaging can work with a flash type of light source which illuminates the whole scene besides splitting a small amount of light into the FMCW sensor for optical mixing. In addition, it can also combine with other types of PIC-based optical technology such as an optical phased array for beam steering on a single chip and enables a hybrid scheme, i.e. partial scene illumination and imaging, for saving optical power or achieving dynamic illumination of a region of interest (RoI).

A light detection and ranging (LiDAR) system according to embodiments of the present invention includes an integrated photonic circuit (PIC) based coherent pixel array sensor that includes a large number of coherent pixel units, such that each pixel receives both the frequency (wavelength) modulated signal light from a local light source (local oscillator or LO) and the returned signal light reflected from targets through an imaging optical system. At each pixel, the LO signal and the returned signal are mixed and detected locally by a mixer and an integrated photodetector, respectively, to enable distance calculation by frequency-modulated continuous wave (FMCW) principle. The LO signal is distributed into each pixel through an on chip optical switch and routing circuit. The LiDAR system in some embodiments also includes a light source, a beam splitting element, an imaging optical system, control and FMCW signal processing circuits, as well as other necessary optical and mechanical components. The LiDAR system in some embodiments also includes an optical phased array for output beam steering which can be standalone or integrated with the coherent pixel array on the same chip.

Additional features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve the above objects, the present invention provides a frequency-modulated continuous wave (FMCW) imaging light detection and ranging (LiDAR) system, which includes: a laser source configured to emit a frequency-modulated, continuous wave optical beam; a beam splitting device configured to split the optical beam emitted by the laser source, to form an illumination optical beam using a first portion of the optical beam and to direct the illumination optical beam into free space to illuminate a target scene; a coherent pixel array sensor, including a spatial array of coherent pixels and an optical distribution circuit; an imaging optical system, configured to image the target scene onto the array of coherent pixels; wherein the beam splitting device is further configured to guide a second portion of the optical beam emitted by the laser source into the optical distribution circuit of the coherent pixel array sensor as a local oscillator signal; wherein the optical distribution circuit is configured to feed a portion of the local oscillator signal to each of the coherent pixels; wherein each coherent pixel is configured to receive a returned optical signal reflected from a section of the target scene that is imaged by the imaging optical system onto the coherent pixel, mix the returned optical signal with the portion of the local oscillator signal into a mixed optical signal, and convert the mixed optical signal into an electrical signal; an FMCW signal processing circuit electrically coupled to the coherent pixel array sensor, configured to read the electrical signal generated by each coherent pixel and to calculate a distance and/or a velocity of the corresponding section of the target scene based on the electrical signal; and a control circuit electrically coupled to the laser source and configured to control the laser source to modulate a frequency of the optical beam, and coupled to the FMCW signal processing circuit and configured to synchronize the modulation of frequency of the optical beam.

It is to be understood that both the foregoing general description and the following detailed description are exemplary and explanatory and are intended to provide further explanation of the invention as claimed.

### BRIEF DESCRIPTION OF THE DRAWINGS

FIG. 1 is a schematic diagram of a scanning FMCW LiDAR system in the prior art.

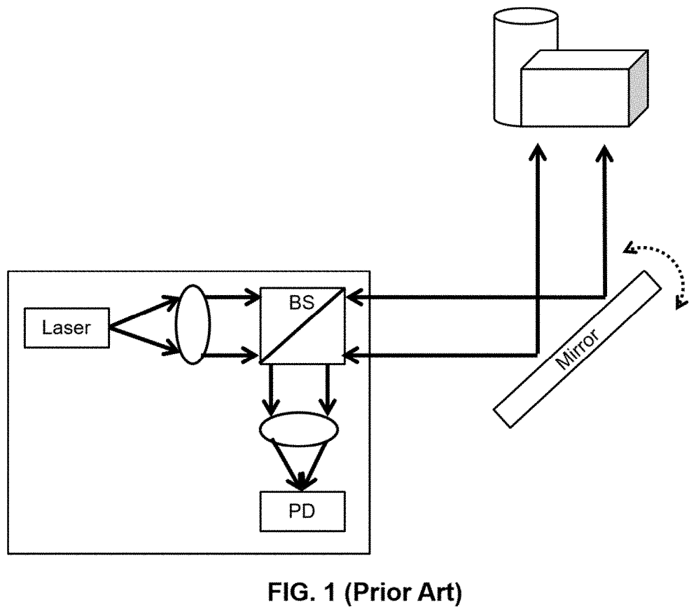

FIG. 2 is a schematic diagram of a LiDAR system according to an embodiment of the present invention.

FIG. 3 is a schematic drawing of a PIC based coherent sensor array and a corresponding FMCW signal processing circuit.

FIG. 4 is a schematic drawing of several pixels of the PIC based coherent sensor array chip in FIG. 3.

FIG. 5 is a schematic design of a LiDAR system according to another embodiment of the present invention.

### DETAILED DESCRIPTION OF PREFERRED EMBODIMENTS

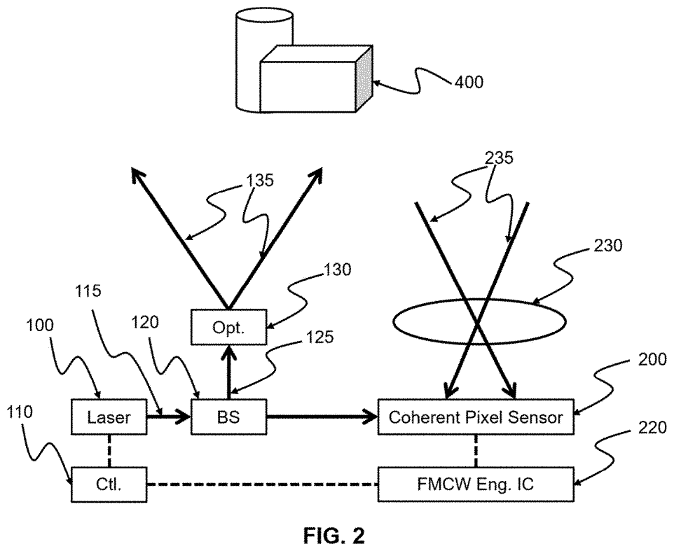

A light detection and ranging (LiDAR) system according to an embodiment of the present invention is schematically shown in FIG. 2. The system includes: a laser source 100 emitting an optical beam 115, a beam splitter 120, an illumination optical system 130, a coherent pixel array sensor chip 200, an imaging optical system 230, a control circuit (integrated circuit, IC) 110 for controlling laser signal, an FMCW signal processing (FMCW engine) IC 220 and necessary electrical, mechanical and interfacing structures to form the LiDAR system that are not shown in the figure.

The laser source 100 is a single mode laser that may be a semiconductor diode laser, a diode-pumped solid-state laser or a fiber laser. The emitting wavelength may be any wavelength from 800 nm to 1600 nm depending on system design choice. A wavelength of 905 nm, 1064 nm, 1310 nm or 1550 nm is often used due to their existing wide use in other applications therefore the abundance of off-the-shelf components while other wavelength may also be used for optimizing the performance of LiDAR for specific applications. A narrow linewidth (wavelength width) is generally preferred in FMCW distance calculation for better phase noise suppression in FMCW. For example, a detection range of 100 m generally prefers a linewidth less than 500 kHz and longer-range demands a smaller value. A diode-pumped solid-state laser or a fiber laser can generally satisfy this linewidth requirement while a semiconductor diode distributed feedback (DFB) laser may have several times larger linewidth and needs an external cavity or filter to achieve the targets. On the other hands, better algorithms may be applied to obtain satisfactory distance calculation precision with a larger bandwidth laser.

In an FMCW detection scheme, the frequency (wavelength) of the laser is modulated, usually linearly, over each period for repeated periods. The total change of wavelength is usually in the range of several nanometers. Such wavelength modulation may be realized by modulating the injected electric current or by modulating the physical size or the refractive index of the laser cavity using thermal or electrical power. The control circuit 110 is used to power the laser light and control the frequency modulation.

The beam splitter 120 is used to emit a majority of the optical power out of the laser source 100 into free space to illuminate a target 400 and split a minority of the optical power into the coherent sensor array 200 as a local oscillator (LO) signal for mixing with returned signal reflected from the target 400. If the output light of the laser source 100 is in free space form, the beam splitter may be realized by a free space optical component such as a prism or a semi-transparent mirror. If the output light of the laser source 100 is optical fiber-coupled, the beam splitter may be realized by an optical fiber-based beam splitter.

The illumination optical system 130 is used to shape the output laser beam 125 out of the beam splitter 120 and transmit the shaped optical beam 135 (the illumination optical beam) to illuminate a target scene. It may increase or decrease the divergence of the beam 135 by using one or multiple optical lenses and may make the output beam 135 more uniform within designed angular range by using one or more optical diffusers.

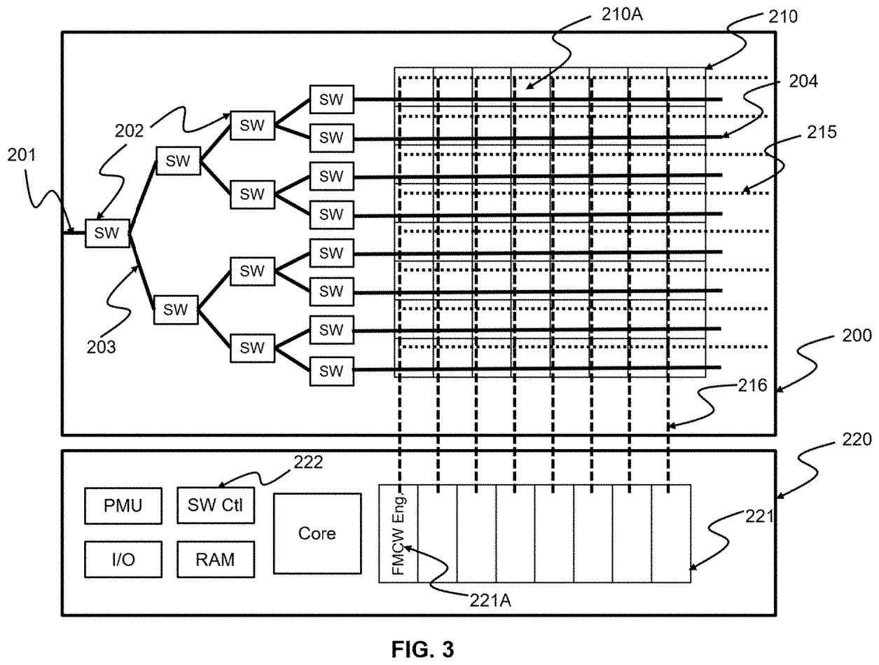

The coherent sensor 200 and the FMCW engine IC 220 are schematically shown in more details in FIG. 3. The FMCW signal processing (FMCW engine) IC 220 is configured to read the mixed and converted electrical signal from each pixel and perform FMCW calculation. It may be a part of the coherent sensor chip 200 or a standalone chip. The FMCW engine IC 220 is electrically connected to control circuit 110 to synchronize (i.e. control the timing of) the frequency modulation of the laser 100.

The coherent sensor 200 is made by silicon (Si) based photonic integrated circuits on bulk Si or Si-on-insulator (SOI) material platform. Si waveguides may be used for wavelengths above 1100 nm while silicon nitride (SiN) waveguide may be used for wavelengths below 1100 nm. The coherent sensor 200 includes:
a spatial array 210 of coherent pixels 210A that can receive the returned optical signal reflected from targets, mix the returned signal with LO signal and convert the mixed optical signal into electrical signal;
an optical distribution circuit that can feed the input LO signal into each pixel 210A for optical mixing; and
and a row-column electrical grid that connects to each pixel 210A and feeds the output electrical signal from the pixels into the FMCW engine 220 to perform distance calculation;

The FMCW engine IC 220 includes an FMCW engine array 221 made of an array of (preferably identical) individual FMCW signal processing circuits or FMCW engines 221A.

The row-column electrical grid of the coherent sensor 200 comprises a plurality of row conductors (metal lines) 215 and a plurality of column conductors (metal lines) 216. Each column metal line 216 is connected to a column of pixels 210A and to an individual FMCW engine 221A of the FMCW engine IC 220. Each row metal line is connected to a row of pixels 210A and also connected to the FMCW engine IC 220. The signal readout is a row-by-row process. The FMCW IC 220 selects a first row metal line such that the electrical signal converted from the photodetector at each pixel of the selected row and all columns is fed into each corresponding individual FMCW engine 221A, and the target distance and the velocity represented by the signal from each of these pixels are calculated simultaneously. By repeating the same process on the rest of the rows, the signals of all the pixels are read out and the target distance and the velocity represented by the signals from all the pixels are calculated so that the distance/velocity calculation of the entire pixel array is completed. Such entire array distance/velocity calculation or a complete depth/velocity map may be repeated at desired constant or varying frame rate to form a depth/velocity map video.

The optical distribution circuit may be made of cascaded multi-stage optical splitters (connected by optical waveguides 203) that split the input LO signal into each pixel 210A. As a row-by-row readout is adopted as stated above, a more efficient way for LO signal distribution is to use cascaded multi-stage optical switches 202 (connected by optical waveguides 203) which may be controlled by a switch control circuit 222 of the FMCW engine IC 220 and to dynamically switch the LO signal to a row optical waveguide 204 corresponding to a pixel row which is currently selected by the FMCW engine 220 to read. In such case, no LO signal is transmitted to other inactive (non-selected) rows and the required LO optical power is reduced. The LO signal in the row optical waveguide 204 of the selected row is split into each pixel of that row through a plurality of optical splitters (described in more detail later).

The LO signal may be coupled into the coherent sensor 200 by a surface-incidence grating coupler or a side-incidence edge coupler 201.

The imaging optical system 230 is made of one or multiple optical lenses to image the target scene that the output beam 135 illuminates onto the array 210 of the pixels of the coherent sensor 200 such that the received optical signal at each pixel 210A corresponds the reflection of a section of the target scene.

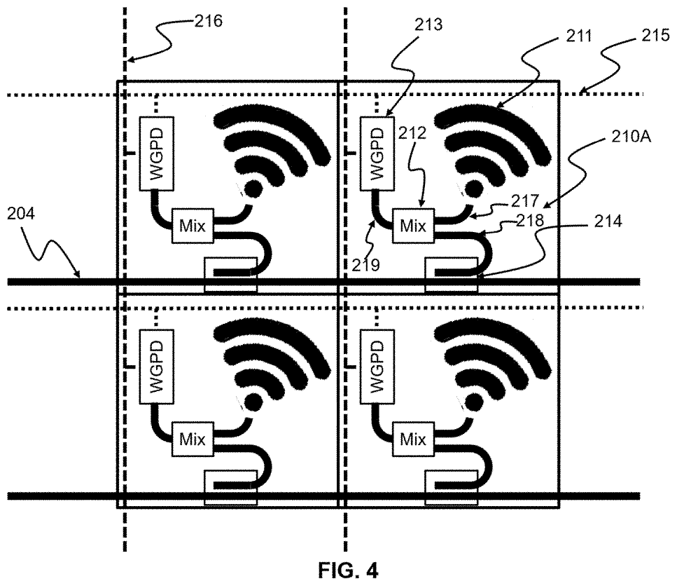

A more detailed design of the Si PIC-based coherent pixel 210A is schematically shown in FIG. 4. Each coherent pixel includes (four pixels are shown in FIG. 4):
A receiving antenna 211, which may be made of a waveguide grating coupler or a micro reflector, for receiving the returned free space signal light and coupling it into an optical waveguide 217;
An optical splitter 214, which may be made of a waveguide-based directional coupler or a multi-mode interferometer (MMI), for splitting a portion of the LO signal light from the row optical waveguide 204 into an optical waveguide 218 for local optical mixing and passing the rest of the light to the next pixel;
An optical mixer 212, which may be made of a waveguide-based directional coupler or an MMI, for combining the LO signal in the optical waveguide 218 with the received optical signal in the optical waveguide 217 in optical domain and output a mixed optical signal to an optical waveguide 219;
A photodetector 213, which may be made of a waveguide germanium (Ge) photodiode for wavelengths below 1600 nm or a Si photodiode for wavelengths below 1100 nm, for converting the mixed optical signal from the optical waveguide 219 into an electrical signal.

It should be noted that the optical splitter 214 may alternatively be viewed as a part of the optical distribution circuit, rather than a part of each coherent pixel.

Each photodetector 213 includes an anode and a cathode which are connected to a corresponding row metal line 215 and a corresponding column metal line 216 respectively. When a row is selected by the FMCW engine IC 220, the photodetector 213 of each pixel 210A in this row is electrically connected a corresponding FMCW engine 221A so that the electrical signal of the photodetector 213 can be read out by the corresponding FMCW engine 221A, and used to perform FMCW calculation to obtain the distance and the velocity information of the scene section that is imaged on to the pixel. Distance and velocity calculation algorithms according to FMCW principles are generally known and will not be described in detail here.

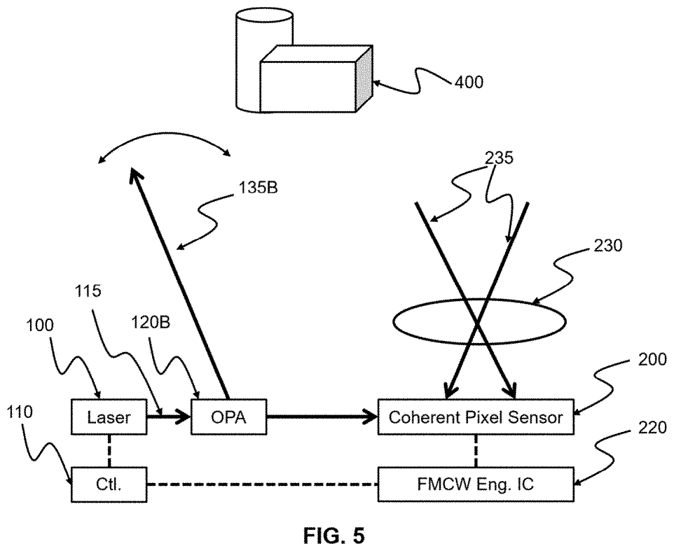

A light detection and ranging (LiDAR) system according to another embodiment of the present invention is schematically shown in FIG. 5. This embodiment is similar to the embodiment of FIG. 2, but the beam splitter 120 of FIG. 2 is replaced by a Si PIC-based optical phased array (OPA) chip 120B as the beam splitting device, and the illumination optical system 130 of FIG. 2 is eliminated. The OPA chip 120B may be implemented on the same coherent sensor chip 200 or on standard-alone chip. In addition to splitting a portion of the laser beam 115 to the coherent sensor 200, the OPA 120B can form an output optical beam 135B with collimated or other desired beam shape and steer the beam 135B to a designated direction to illuminate selected regions of a target scene 400.

When the OPA 120B is used with the coherent sensor 200, a hybrid scanning-imaging scheme may be implemented. In this scheme, the OPA 120B emits a line-shaped beam with a large field-of-divergence in the row direction of the coherent pixel array 210 and a narrow field-of-divergence, i.e. near collimation, in the column direction of the coherent pixel array (i.e., the region illuminated by the line-shaped beam will be imaged by the imaging optical system 230 onto one or small number of rows of the coherent pixel array). Since the coherent pixels in the coherent pixel array 210 are read out row-by-row, the OPA 120B can steer this line-shaped beam row-by-row in synchronization with the pixel readout such that the region of the target scene 400 corresponding to a specific row of pixels is being illuminated by the OPA beam 135B while this row of pixels are being read out. Such scheme saves the total optical power required by the system which only needs to illuminate the region of the target scene that is actively being read and calculated at the corresponding coherent pixels 210A through the imaging optical system 230. The power saving benefits both system power budget and eye-safety concern.

It will be apparent to those skilled in the art that various modification and variations can be made in the coherent pixel array sensor based FMCW imaging LiDAR and related method of the present invention without departing from the spirit or scope of the invention. Thus, it is intended that the present invention cover modifications and variations that come within the scope of the appended claims and their equivalents.

What is claimed is:

1. A frequency-modulated continuous wave (FMCW) imaging light detection and ranging (LiDAR) system, comprising:
a laser source configured to emit a frequency-modulated, continuous wave optical beam;
a beam splitting device configured to split the optical beam emitted by the laser source, to form an illumination optical beam using a first portion of the optical beam and to direct the illumination optical beam into free space to illuminate a target scene;
a coherent pixel array sensor, including a spatial array of coherent pixels and an optical distribution circuit;
an imaging optical system, configured to image the target scene onto the array of coherent pixels;
wherein the beam splitting device is further configured to guide a second portion of the optical beam emitted by the laser source into the optical distribution circuit of the coherent pixel array sensor as a local oscillator signal;
wherein the optical distribution circuit is configured to feed a portion of the local oscillator signal to each of the coherent pixels;
wherein each coherent pixel is configured to receive a returned optical signal reflected from a section of the target scene that is imaged by the imaging optical system onto the coherent pixel, mix the returned optical signal with the portion of the local oscillator signal into a mixed optical signal, and convert the mixed optical signal into an electrical signal;
an FMCW signal processing circuit electrically coupled to the coherent pixel array sensor, configured to read the electrical signal generated by each coherent pixel and to calculate a distance and/or a velocity of the corresponding section of the target scene based on the electrical signal; and
a control circuit electrically coupled to the laser source and configured to control the laser source to modulate a frequency of the optical beam, and coupled to the FMCW signal processing circuit and configured to synchronize the modulation of frequency of the optical beam.

2. The FMCW imaging LiDAR system of claim 1, wherein each coherent pixel of the coherent pixel array sensor includes:
a receiving antenna configured to receive the returned optical signal;
an optical mixer configured to combine the portion of the local oscillator signal from the optical distribution circuit with the received returned optical signal in optical domain and to output a mixed optical signal; and
a photodetector configured to convert the mixed optical signal into the electrical signal.

3. The FMCW imaging LiDAR system of claim 2, wherein the coherent pixel array sensor is made of silicon (Si) based photonic integrated circuits on bulk Si or Si-on-insulator (SOI) material platform, and wherein in each coherent pixel, the receiving antenna is made of a waveguide grating coupler or a micro reflector, the optical mixer is made of a waveguide-based directional coupler or a multi-mode interferometer, and the photodetector is made of a waveguide germanium (Ge) photodiode or a Si photodiode.

4. The FMCW imaging LiDAR system of claim 2,
wherein the FMCW signal processing circuit includes a plurality of individual FMCW processing circuits,
wherein the coherent pixel array sensor further includes a row-column electrical grid having a plurality of row conductors and a plurality of column conductors, wherein each column conductor is coupled to a column of the coherent pixels and to one of the individual FMCW signal processing circuit, and each row conductor is coupled to a row of the coherent pixels and to the FMCW signal processing circuit,
wherein the FMCW signal processing circuit reads the array of coherent pixels using a row-by-row process, by selecting one row of the coherent pixels at a time using the row conductors and reading out the electrical signal generated by each coherent pixel of the selected row by a corresponding individual FMCW signal processing circuit using the column conductors.

5. The FMCW imaging LiDAR system of claim 4, wherein the optical distribution circuit of the coherent pixel array sensor includes a plurality of row optical waveguides each corresponding to a row of the coherent pixels, cascaded multi-stage optical switches that selectively couple the local oscillator signal to one or more of the row optical waveguides, and an optical splitter for each coherent pixel, wherein the optical splitter for each coherent pixel is coupled to one of the row optical waveguides and configured to split a portion of the local oscillator signal in the row optical waveguide and transmit it to the optical mixer of the coherent pixel and to pass the rest of the local oscillator signal, and
wherein the FMCW signal processing circuit further includes a switch control circuit coupled to the cascaded multi-stage optical switches and configured to control the cascaded multi-stage optical switches to selectively couple the local oscillator signal only to the row optical waveguide corresponding to the row of coherent pixels currently selected by the row conductors for read out.

6. The FMCW imaging LiDAR system of claim 4, wherein the beam splitting device includes an optical phased array configured to form a line-shaped the illumination optical beam having a wider field-of-divergence in a direction corresponding to a row direction of the coherent pixel array and a narrower field-of-divergence in a direction corresponding to a column direction of the coherent pixel array, and to steer the line-shaped illumination optical beam in the direction corresponding to the column direction of the coherent pixel array to illuminate selected regions of the target scene corresponding to the row of coherent pixels currently selected by the row conductors for read out.

7. The FMCW imaging LiDAR system of claim 2, wherein the optical distribution circuit of the coherent pixel array sensor includes a plurality of row optical waveguides each corresponding to a row of coherent pixels, cascaded multi-stage optical splitters that couple the local oscillator signal to each row optical waveguide, and an optical splitter for each coherent pixel, wherein the optical splitter for each coherent pixel is coupled to one of the row optical waveguides and configured to split a portion of the local oscillator signal in the row optical waveguide and transmit it to the optical mixer of the coherent pixel and to pass the rest of the local oscillator signal.

8. The FMCW imaging LiDAR system of claim 1, wherein the beam splitting device includes a beam splitter which is a prism, a semi-transparent mirror, or an optical fiber-based beam splitter, and an illumination optical system configured to shape the first portion of the optical beam emitted by the beam splitter into the illumination optical beam and transmit the illumination optical beam to illuminate the target scene.

9. The FMCW imaging LiDAR system of claim 1, wherein the beam splitting device includes an optical phased array configured to form a collimated or shaped beam as the illumination optical beam.
